(19) United States
(12) Patent Application Publication
(10) Pub. No.: US 2010/0013039 A1
(43) Pub. Date: Jan. 21, 2010

(54) Backside-illuminated imaging sensor including backside passivation

(75) Inventors: Yin Qian, Milpitas, CA (US); Hsin-Chih Tai, Cupertino, CA (US); Vincent Venezia, Sunnyvale, CA (US); Duli Mao, Sunnyvale, CA (US); Howard E. Rhodes, San Martin, CA (US)

Correspondence Address: BLAKELY SOKOLOFF TAYLOR & ZAFMAN LLP, 1279 Oakmead Parkway, Sunnyvale, CA, 94085-4040, US

(73) Assignee: OMNIVISION TECHNOLOGIES, INC., Sunnyvale, CA (US)

(21) Appl. No.: 12/177,035

(22) Filed: Jul. 21, 2008

(51) Int. Cl. H01L 27/146; H01L 21/00

(52) U.S. Cl. 257/432; 438/66; 257/E27.13

(57) ABSTRACT

The disclosure describes embodiments of a process comprising forming a pixel on a frontside of a substrate, the substrate having a frontside, a backside, and a thickness substantially equal to a distance between the frontside and the backside. The thickness of the substrate is reduced by removing material from the backside of the substrate to allow for backside illumination of the pixel, and the backside of the substrate is treated with a hydrogen plasma to passivate the backside. The disclosure also describes embodiments of an apparatus comprising a semiconductor wafer having a frontside, a backside, and a thickness substantially equal to a distance between the frontside and the backside, and a pixel formed on the frontside, wherein the thickness of the wafer is selected and adjusted to allow for illumination of the pixel through the backside of the wafer, and wherein the backside is treated with a hydrogen plasma to passivate the backside.

### TECHNICAL FIELD

The present invention relates generally to imaging sensors and in particular, but not exclusively, to backside-illuminated imaging (BSI) sensors.

### BACKGROUND

Backside-illuminated imaging (BSI) sensors include imaging pixel arrays that are fabricated on the frontside of a semiconductor substrate, but can nonetheless capture images using light received through the backside of the substrate. The backside of silicon BSI sensors must be thinned by removing material from the backside of the substrate to allow nearby collection photodiodes to generate and collect the related charge. This wafer thinning step is normally combined with mechanical grinding and a chemical wet etch. To reduce the color cross talk and improve quantum efficiency, the wafer thickness is often reduced to a few microns. After wafer thinning, a cleaning step is used to remove particles and other contaminants from the wafer. Certain implant steps are also used after wafer thinning to improve the sensor performance, such as laser/thermal annealing that is applied to activate the implanted dopants.

During BSI wafer thinning, many defects such as dangling silicon bonds may be created. These dangling bonds, if not removed, often can become dark current generation centers that degrade the image sensor performance. Dark current is current that flows in an imaging sensor in the absence of incident light on the imaging sensor.

One approach to removing the dangling bonds has been to apply a mild annealing to the wafer at a temperature of at least 650° C., but this can be problematic because the wafer thinning process described above is typically done after formation of the pixels, vias and interconnects. After formation of the pixels, vias and interconnects the process temperature should typically not exceed 410° C. to avoid damage to the front side metal, as well as the silicide.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a cross-sectional view of an embodiment of a manufacturing assembly used to manufacture an embodiment of a backside-illuminated image sensor.

FIG. 2 is a cross-sectional view of the embodiment of the manufacturing assembly shown in FIG. 1 after removal of material from a backside of the substrate.

FIG. 3 is a cross-sectional view of the manufacturing assembly embodiment shown in FIG. 2 during a dopant implantation.

FIG. 4 is a cross-sectional view of the manufacturing assembly embodiment shown in FIG. 3 during hydrogen plasma treatment.

FIG. 5 is a cross-sectional view of the manufacturing assembly embodiment shown in FIG. 4 after an anti-reflective coating has been applied to the backside substrate.

FIG. 6 is a block diagram of an embodiment of an imaging system that can be used together with an embodiment of a backside-illuminated image sensor whose manufacture is shown in FIGS. 1-5.

### DETAILED DESCRIPTION OF THE ILLUSTRATED EMBODIMENTS

Embodiments of a process, apparatus and system for treatment of a backside-illuminated imaging sensor are described herein. In the following description, numerous specific details are described to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail but are nonetheless encompassed within the scope of the invention.

Reference throughout this specification to “one embodiment” or “an embodiment” means that a particular feature, structure, or characteristic described in connection with the embodiment is included in at least one embodiment of the present invention. Thus, appearances of the phrases “in one embodiment” or “in an embodiment” in this specification do not necessarily all refer to the same embodiment. Furthermore, the particular features, structures, or characteristics may be combined in any suitable manner in one or more embodiments.

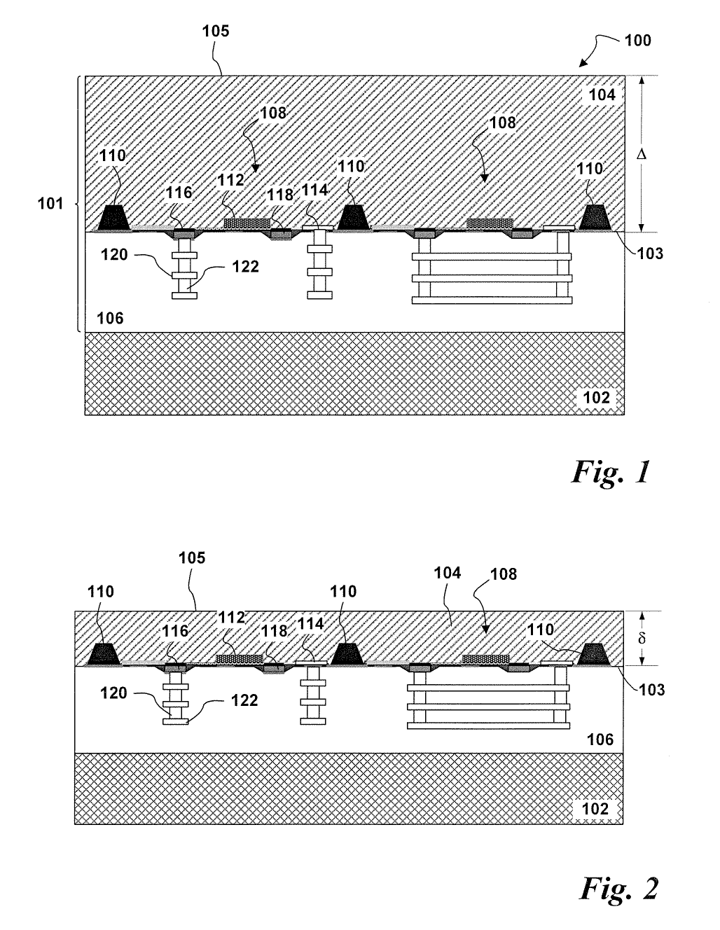

FIG. 1 illustrates an embodiment of a manufacturing assembly 100 for manufacturing an embodiment of a backside-illuminated image sensor. Manufacturing assembly 100 comprises an image sensor 101 coupled to a carrier wafer 102. In most embodiments, carrier wafer 102 can be removed when manufacturing is complete.

Image sensor 101 includes a substrate 104 having a frontside 103, a backside 105, and an initial thickness Δ separating frontside 103 from backside 105. Substrate 104 can be a semiconductor material, and in various embodiments can be a p-type semiconductor, an n-type semiconductor, an un-doped (i.e., neither p-type nor n-type) semiconductor, or some combination of the listed semiconductor types. In some embodiments, substrate 104 can include therein circuitry to control image sensor 101 and/or process the signals from the pixels of the image sensor.

A plurality of individual pixels 108 are formed on frontside 103 of substrate 104, and each individual pixel 108 is separated and electrically isolated from adjacent pixels by shallow trench isolations (STIs) 110. The term pixel as used herein is meant to encompass all pixel designs, including CMOS pixels, CCD pixels, etc. Although only two pixels 108 are illustrated in the figure, embodiments of image sensor 101 can of course include many more pixels, usually arranged into a pixel array that can be used for image capture. In one embodiment, pixels 108 are active pixels that uses four transistors (known as 4T active pixels), but in other embodiments pixels 108 could include more or less transistors and in still other embodiments each pixel 108 need not use the same number of transistors as other pixels. Each pixel 108 is formed in frontside 103 of substrate 104 and includes a photodiode 112, a floating node 114, and transfer gate 118 that transfers charge accumulated in photodiode 112 to floating node 114. Although described as a photodiode, in other embodiments photodiode 112 can be any kind of photodetector element, such as any type of photogate or photocapacitor.

In operation of each pixel 108, during an integration period (also referred to as an exposure period or accumulation period) photodiode 112 receives incident light from one or both of frontside 103 and backside 105 and generates a corresponding electrical charge that is held in the photodiode. At the end of the integration period, charge held in the photodiode is transferred into floating node 114 by applying a voltage pulse to transfer gate 118. When the signal has been transferred to floating node 114, transfer gate 118 is turned off again for the start of another integration period of photodiode 112. After the signal has been transferred from photodiode 112 to floating node 114, the signal held in floating node 114 is used to modulate an amplification transistor (not shown), and an address transistor 122 (also not shown) is used to address the pixel and to selectively read out the signal onto the signal line. After readout through the signal line, a reset transistor 120 resets floating node 114 to a reference voltage, which in one embodiment is V_{dd}.

After formation of pixels 108 in substrate 104, a dielectric layer 106 is mounted onto frontside 103 of substrate 104. Dielectric layer 106 has formed therein various layers of conductive traces 120, as well as vias 122 that electrically couple the different layers of conductive traces. Traces 120 and vias 122 provide the electrical interconnections that allow signals to be sent to and retrieved from each pixel 108 in image sensor 101.

A carrier wafer 102 is attached to the side of dielectric layer 106 opposite the side where the dielectric layer is coupled to substrate 104. Among other things, carrier wafer 102 provides physical support for dielectric layer 106 and substrate 104 so that these two layers are not damaged by forces applied to manufacturing assembly 100 during the different steps involved in manufacturing. In different embodiments, carrier wafer 102 can be made up of various materials such as silicon. In an embodiment where image sensor 101 is to be used exclusively with backside illumination, carrier wafer 102 can be left attached to the other layers if necessary, but in embodiments where image sensor 101 will be used with both frontside and backside illumination carrier wafer 102 can be removed.

FIG. 2 illustrates a subsequent state of manufacturing assembly 100. Starting with the manufacturing assembly shown in FIG. 1, the initial thickness Δ of substrate 104 is reduced to a smaller thickness 6 by removing material from backside 105. Thinning substrate 104 from its initial thickness Δ to a smaller thickness δ allows for more efficient backside illumination of pixels 108. Reducing the thickness of substrate 104 can be accomplished differently in different embodiments. In one embodiment, substrate 104 can be thinned by removing material from backside 105 using chemical mechanical polishing (CMP), but in other embodiments material can be removed by other techniques such as wet or dry chemical etching. In still other embodiments, material can be removed from the backside using a combination of mechanical and chemical techniques or a combination of different chemical techniques.

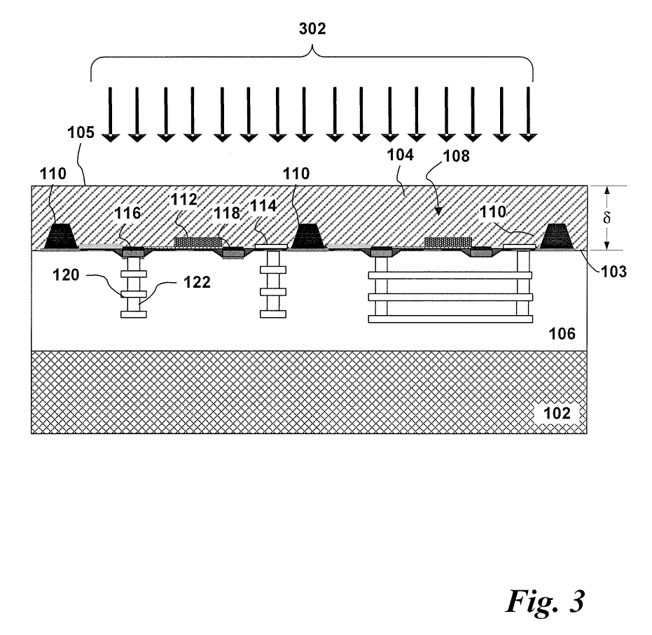

FIG. 3 illustrates a subsequent state of manufacturing assembly 100. Starting with the manufacturing assembly as shown in FIG. 2, one or more dopants 302 are implanted into substrate 104 by bombarding backside 105. In other embodiments, implantation need not wait until substrate 104 has been thinned to reduced thickness 6, but can instead be done when substrate 104 is at its initial thickness Δ as shown in FIG. 1. Dopant implantation can create the p-n junctions needed for the photodiode 112 to function or, where the p-n junction existed before implantation, dopant implantation can help tailor and improve the performance characteristics of pixels 108, such as by improving color cross talk. The exact dopants or dopant combinations used, as well as their dosage, implantation energy and final concentration, will depend on the desired pixel performance characteristics. In on embodiment, phosphorus and/or boron can be used as dopants, but of course in other embodiments other dopants or combinations of dopants can be used. In addition to dopant implantation, a laser anneal or thermal anneal may also be used to activate the implanted dopant or dopants.

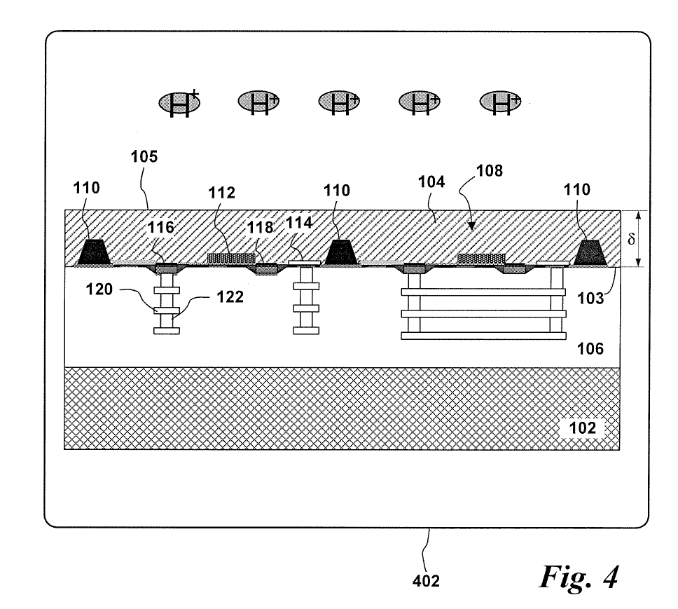

FIG. 4 illustrates a subsequent state of manufacturing assembly 100. During backside material removal between the manufacturing assembly in FIGS. 1 and 2, dangling silicon bonds can be created on or near the backside 105 where the material was removed. Normally silicon oxide (nominally SiO or SiO₂) is used to passivate these dangling bonds. Typically, forming the needed silicon oxide requires high temperatures that would ruin interconnects 120 and vias 122 in dielectric layer 106. In an embodiment where interconnects 120 and vias 122 are made of aluminum, the temperature must remain below 450 C to avoid melting and/or evaporating the vias and interconnects. Not only would the high temperatures melt and/or evaporate interconnects 120 and vias 122, but also small bubbles created during the bonding process for wafer carrier 102 can get larger and push apart the seam between the wafer carrier and the dielectric layer.

Starting with the manufacturing assembly 100 as shown in FIG. 3, hydrogen plasma is used to treat the surface of backside 108. Manufacturing assembly 100 is first placed in a chamber 402, where its backside 105 is treated with hydrogen plasma to passivate the dangling bonds created by thinning substrate 104. In various embodiments, the hydrogen plasma may be generated remotely or on-site (i.e., in the chamber) by RF or DC means. In an embodiment in which the hydrogen plasma is generated on-site, a gas is flowed into chamber 402 while conditions inside the chamber—the temperature and pressure of the gas inside chamber 402, and energy such as radio frequency (RF) that is applied to the gas—are adjusted to create hydrogen plasma from the gas.

In various embodiments, the gas flowed into the chamber can be any one of hydrogen (H₂), silane (SiH₄) and ammonia (NH₃), although in other embodiments the gas used can be a mixture of these or any other suitable gas for hydrogen plasma. In one embodiment, the selected gas is flowed into chamber 402 at a gas flow rate of 10,000 standard cubic centimeters per minute (SCCM) while the chamber pressure ranges between about 0.1 mTorr and about 100 Torr, the temperature ranges between about 100° C. and about 400° C., and an RF power between about 10 and about 1000 Watts is applied to the gas. In various embodiments, the time period of the plasma treatment of the backside can vary from about 0.1 seconds to about 1000 seconds. Because the plasma treatment is performed at a relatively low temperature—hydrogen plasma treatments can have temperatures as low as 100° C. that will not damage metal structures—it is suitable for the backside silicon surface treatment of manufacturing assembly 100.

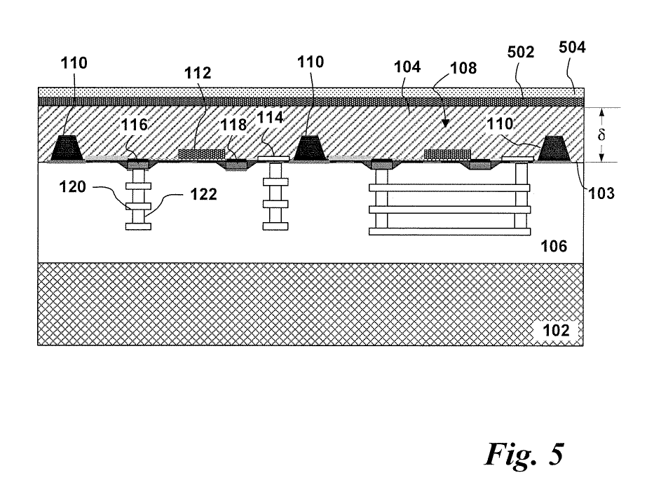

FIG. 5 illustrates a subsequent state of manufacturing assembly 100. Starting with the manufacturing assembly as shown in FIG. 4, an anti-reflective coating (ARC) layer 502 is deposited on backside 105 using a plasma-enhanced chemical vapor deposition (PECVD) process. Typically ARC layer 502 is an insulator that prevents the reflection of light incident on backside 105. Additional layers 504 can also be added to backside 105 for different purposes.

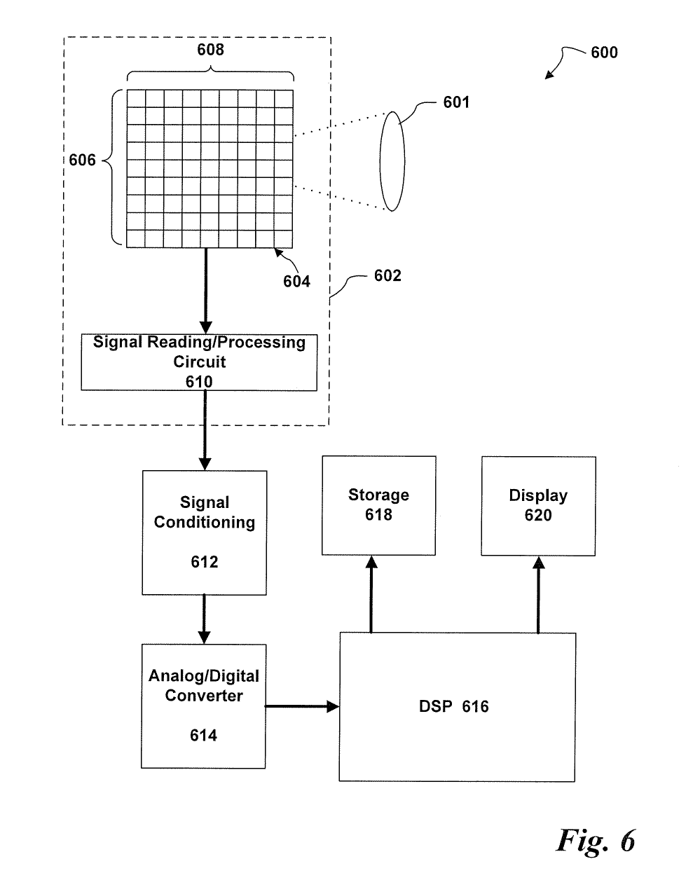

FIG. 6 illustrates an embodiment of an imaging system 600. Optics 601, which can include refractive, diffractive or reflective optics or combinations of these, are coupled to image sensor 602 to focus an image onto the pixels in pixel array 604 of the image sensor. Pixel array 604 captures the image and the remainder of imaging system 600 processes the pixel data from the image.

Image sensor 602 comprises a pixel array 604 and a signal reading and processing circuit 160. Pixel array 604 is two-dimensional and includes a plurality of pixels arranged in rows 606 and columns 608. During operation of pixel array 604 to capture an image, each pixel in pixel array 604 captures incident light (i.e., photons) during a certain exposure period and converts the collected photons into an electrical charge. The electrical charge generated by each pixel can be read out as an analog signal, and a characteristic of the analog signal such as its charge, voltage or current will be representative of the intensity of light that was incident on the pixel during the exposure period.

Illustrated pixel array 604 is regularly shaped, but in other embodiments the array can have a regular or irregular arrangement different than shown and can include more or less pixels, rows, and columns than shown. Moreover, in different embodiments pixel array 604 can be a color image sensor including red, green, and blue pixels designed to capture images in the visible portion of the spectrum, or can be a black-and-white image sensor and/or an image sensor designed to capture images in the invisible portion of the spectrum, such as infra-red or ultraviolet.

Image sensor 602 includes signal reading and processing circuit 610. Among other things, circuit 610 can include circuitry and logic that methodically reads analog signals from each pixel, filters these signals, corrects for defective pixels, and so forth. In an embodiment where circuit 610 performs only some reading and processing functions, the remainder of the functions can be performed by one or more other components such as signal conditioner 612 or DSP 616. Although shown in the drawing as an element separate from pixel array 604, in some embodiments reading and processing circuit 610 can be integrated with pixel array 604 on the same substrate or can comprise circuitry and logic embedded within the pixel array. In other embodiments, however, reading and processing circuit 610 can be an element external to pixel array 604 as shown in the drawing. In still other embodiments, reading and processing circuit 610 can be an element not only external to pixel array 604, but also external to image sensor 602.

Signal conditioner 612 is coupled to image sensor 602 to receive and condition analog signals from pixel array 604 and reading and processing circuit 160. In different embodiments, signal conditioner 612 can include various components for conditioning analog signals. Examples of components that can be found in signal conditioner include filters, amplifiers, offset circuits, automatic gain control, etc. In an embodiment where signal conditioner 612 includes only some of these elements and performs only some conditioning functions, the remaining functions can be performed by one or more other components such as circuit 610 or DSP 616. Analog-to-digital converter (ADC) 614 is coupled to signal conditioner 612 to receive conditioned analog signals corresponding to each pixel in pixel array 604 from signal conditioner 612 and convert these analog signals into digital values.

Digital signal processor (DSP) 616 is coupled to analog-to-digital converter 614 to receive digitized pixel data from ADC 614 and process the digital data to produce a final digital image. DSP 616 can include a processor and an internal memory in which it can store and retrieve data. After the image is processed by DSP 616, it can be output to one or both of a storage unit 618 such as a flash memory or an optical or magnetic storage unit and a display unit such as an LCD screen.

The above description of illustrated embodiments of the invention, including what is described in the abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize. These modifications can be made to the invention in light of the above detailed description.

The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

1. A process comprising:
forming a pixel on a frontside of a substrate, the substrate having a frontside, a backside, and a thickness substantially equal to a distance between the frontside and the backside;
reducing the thickness of the substrate by removing material from the backside of the substrate to allow for backside illumination of the pixel; and
treating the backside of the substrate with a hydrogen plasma to passivate the backside.

2. The process of claim 1 wherein passivating the backside comprises passivating dangling silicon bonds created while reducing the thickness of the substrate.

3. The process of claim 1 wherein treating the backside of the substrate with the hydrogen plasma comprises using one or more of hydrogen (H₂), silane (SiH₄) and ammonia (NH₃), or other suitable gases.

4. The process of claim 3 wherein treating of the backside of the substrate with the hydrogen plasma occurs at a temperature between approximately 100° C. and approximately 400° C.

5. The process of claim 1 wherein reducing the thickness of the substrate comprises removing material from the backside using at least one of a mechanical grinding process and a chemical wet etch process.

6. The process of claim 1, further comprising implanting the backside of the substrate with one or more dopants before reducing the thickness of the substrate.

7. The process of claim 6 wherein the dopants can include boron or phosphorous.

8. The process of claim 6 wherein a thermal anneal is performed after implanting the backside with the dopants.

9. The process of claim 1 wherein treating the backside with hydrogen plasma is included in an anti-reflective coating deposition process.

9. An apparatus comprising:
a semiconductor wafer having a frontside, a backside, and a thickness substantially equal to a distance between the frontside and the backside; and
a pixel formed on the frontside, wherein the thickness of the wafer is selected and adjusted to allow for illumination of the pixel through the backside of the wafer, and wherein the backside is treated with a hydrogen plasma to passivate the backside.

10. The apparatus of claim 9, further comprising an imaging array including the pixel formed on the frontside of the wafer.

11. The apparatus of claim 9 wherein the backside of the wafer is treated with the hydrogen plasma to passivate broken silicon bonds created during at least one of a mechanical grinding and a chemical wet etch of the backside of the wafer.

12. The apparatus of claim 9 wherein the backside of the wafer includes an anti-reflective coating.

13. The apparatus of claim 9 wherein the backside of the wafer is implanted with one or more dopants.

14. The apparatus of claim 13 wherein the dopants can be boron or phosphorus.

15. An image sensor system comprising:
a backside-illuminated pixel array formed in a substrate, wherein the backside of the substrate is treated with a hydrogen plasma to passivate a surface of the backside; and
processing circuitry coupled to the pixel array to process a signal received from the pixel array.

16. The system of claim 15 wherein the backside of the substrate is passivated with a hydrogen plasma gas including one or more of hydrogen (H₂), silane (SiH₄) and ammonia (NH₃).

17. The system of claim 15 wherein the backside of the substrate includes an anti-reflective coating (ARC).

18. The system of claim 15, further comprising a digital signal processor coupled to the image sensor to process the signals received from the image sensor.

19. The system of claim 15, further comprising an optical element optically coupled to the pixel array.
